(19) United States
(12) Patent Application Publication
(10) Pub. No.: US 2012/0306009 A1
(43) Pub. Date: Dec. 6, 2012

(54) INTEGRATION OF SUPERJUNCTION MOSFET AND DIODE

(76) Inventor: Suku Kim, South Jordan, UT (US)

(21) Appl. No.: 13/153,178

(22) Filed: Jun. 3, 2011

(51) Int. Cl. H01L 27/06; H01L 21/8234

(52) U.S. Cl. 257/334; 438/237; 257/E27.016; 257/E21.629

(57) ABSTRACT

A semiconductor structure comprises a semiconductor layer of a first conductivity type, trenches extending into the semiconductor layer, and a conductive layer of a second conductivity type lining sidewalls and bottom of each trench and forming PN junctions with the semiconductor layer. A first plurality of the trenches are disposed in a field effect transistor region that comprises a body region of the first conductivity type, source regions of the second conductivity type in the body region, and gate electrodes isolated from the body region and the source regions by a gate dielectric. A second plurality of the trenches are disposed in a Schottky region that comprises a conductive material contacting mesa surfaces of the semiconductor layer between adjacent ones of the second plurality of the trenches to form Schottky contacts. The conductive material also contacts the conductive layer proximate an upper portion of the second plurality of the trenches.

### FIELD OF THE INVENTION

This application relates to power semiconductor devices and methods for making such devices. More specifically, this application describes the integration of superjunction metal oxide semiconductor field effect transistors (MOSFETs) with Schottky-based diodes.

### BACKGROUND

Low voltage MOSFET devices can be monolithically integrated with Schottky diodes to provide a number of benefits. Some of the benefits include increased reverse recovery, reduced forward voltage drop, and lower device costs. This same approach has not been feasible for high voltage MOSFET devices, however, because leakage of conventional Schottky diodes is too high. Instead of integrating high voltage MOSFET devices with Schottky diodes, the high voltage MOSFET devices are often paired with external PN diodes. While this combination can improve leakage, the resulting reverse recovery is often slow and snappy. Methods that control carrier lifetime have been used to improve reverse recovery. These methods include electron irradiation and metal diffusion. These methods can be difficult to control, however, and can lead to defect and leakage issues.

Thus, there is a need for high voltage MOSFET devices having improved performance, lower device costs, and simpler methods for manufacture and use.

### SUMMARY

Embodiments of the present invention monolithically integrate superjunction MOSFETs with Schottky-based diodes to provide high voltage MOSFET devices having improved performance, lower device costs, and simpler methods of manufacture and use. The Schottky-based diodes include Schottky diodes having Schottky contacts with mesa surfaces between adjacent trenches in particular regions of the device. The Schottky-based diodes also include PN diodes forming PN junctions with a drift region of the device. As examples, the Schottky-based diodes may include Junction Barrier Schottky (JBS) and Merged Pin Schottky (MPS) type diodes. These Schottky-based diodes have reduced leakage, reduced stored charge, lower peak reverse current, and softer recovery than conventional PN diodes. This can reduce power loss and stress during fast switching modes and can reduce forward voltage drop. Monolithically integrating superjunction MOSFETs with these Schottky-based diodes can provide improved reverse recovery without requiring carrier lifetime controls.

In accordance with an embodiment of the invention, a monolithically integrated superjunction MOSFET and Schottky-based diode comprises a semiconductor layer of a first conductivity type, trenches extending into the semiconductor layer, and a conductive layer of a second conductivity type lining sidewalls and bottom of each trench. The conductive layer of the second conductivity type forms PN junctions with the semiconductor layer. A first plurality of the trenches are disposed in a field effect transistor (FET) region. The FET region may comprise a body region of the first conductivity type in the semiconductor layer, source regions of the second conductivity type in the body region, and gate electrodes isolated from the body region and the source regions by a gate dielectric. A second plurality of the trenches are disposed in a Schottky region. The Schottky region may comprise a conductive material contacting mesa surfaces of the semiconductor layer between adjacent ones of the second plurality of the trenches to form Schottky contacts. The conductive material may also contact the conductive layer proximate an upper portion of the second plurality of the trenches.

In one embodiment, the monolithically integrated superjunction MOSFET and Schottky-based diode may further comprise a dielectric material substantially filling a center portion of each trench between the conductive layer lining the sidewalls and the bottom of each trench.

In another embodiment, the first conductivity type is p-type and the second conductivity type is n-type.

In another embodiment, the first conductivity type is n-type and the second conductivity type is p-type.

In another embodiment, the semiconductor layer extends over a substrate of the second conductivity type and the trenches extend through the semiconductor layer.

In another embodiment, the semiconductor layer comprises an epitaxial layer.

In another embodiment, one of the gate electrodes are disposed in each of the first plurality of the trenches, and the body region and the source regions abut the sidewalls of the first plurality of the trenches.

In another embodiment, the conductive material forms Schottky contacts with the conductive layer in the Schottky region.

In yet another embodiment, the conductive material comprises metal.

In accordance with another embodiment of the invention, a semiconductor structure comprises a field effect transistor (FET) region that includes a body region of a first conductivity type in a semiconductor region, source regions of a second conductivity type in the body region, gate electrodes isolated from the body region and the source regions by a gate dielectric, and a conductive material extending over the FET region and contacting the source regions. The semiconductor structure also comprises a Schottky region that includes a first plurality of trenches extending into the semiconductor region, and a conductive layer of the second conductivity type lining sidewalls and bottom of each of the first plurality of trenches and forming PN junctions with the semiconductor region. The conductive material may extend over the Schottky region and contact mesa surfaces of the semiconductor region between adjacent ones of the first plurality of trenches and contact the conductive layer proximate an upper portion of the first plurality of trenches.

In one embodiment, the conductive material forms Schottky contacts with the mesa surfaces of the semiconductor region and with the conductive layer proximate the upper portion of the first plurality of trenches.

In another embodiment, the conductive material comprises metal.

In another embodiment, the semiconductor region comprises an epitaxial layer of the first conductivity type extending over a substrate of the second conductivity type, and the first plurality of trenches extend through the epitaxial layer.

In another embodiment, the gate electrodes are disposed over an upper surface of the semiconductor region, the gate dielectric extending between each gate electrode and the semiconductor region, and each gate electrode overlaps the body region and one of the source regions along the upper surface of the semiconductor region.

In another embodiment, the FET region further comprises a second plurality of trenches extending into the semiconductor region, the conductive layer lining sidewalls and bottom of each of the second plurality of trenches and forming PN junctions with the semiconductor region. One of the gate electrodes may be disposed in each of the second plurality of trenches, and the body region and the source regions may abut the sidewalls of the second plurality of trenches.

In yet another embodiment, the semiconductor structure further comprises a dielectric material substantially filling a center portion of each of the first plurality of trenches between the conductive layer lining the sidewalls and the bottom of each of the first plurality of trenches.

In accordance with another embodiment of the present invention, a method of forming a semiconductor structure having a field effect transistor (FET) region and a Schottky region includes forming trenches extending into a semiconductor region, and forming a conductive layer lining sidewalls and bottom of each trench. The conductive layer may form PN junctions with the semiconductor region. In the FET region, a body region of a first conductivity type is formed in the semiconductor region, source regions of a second conductivity type are formed in the body region, and gate electrodes are formed that are isolated from the body region and the source regions by a gate dielectric. In the Schottky region, a conductive material is formed contacting mesa surfaces of the semiconductor region between adjacent ones of the trenches to form Schottky contacts and contacting the conductive layer proximate an upper portion of the trenches.

In one embodiment, the conductive material forms Schottky contacts with the conductive layer in the Schottky region.

In another embodiment, the conductive layer comprises metal.

In another embodiment, forming the conductive layer comprises growing an epitaxial layer along the sidewalls and the bottom of each trench.

In another embodiment, forming the conductive layer comprises implanting a dopant into the sidewalls and the bottom of each trench.

In another embodiment, the semiconductor region comprises an epitaxial layer of the first conductivity type extending over a substrate of the second conductivity type, and the trenches extend through the epitaxial layer.

In another embodiment, the trenches are formed only in the Schottky region, and in the FET region the gate electrodes are formed over an upper surface of the semiconductor region such that the gate dielectric extends between each gate electrode and the semiconductor region. Each gate electrode may overlap the body region and at least one of the source regions along the upper surface of the semiconductor region.

In yet another embodiment, one of the gate electrodes are formed in each of the trenches in the FET region, and the body region and the source regions abut the sidewalls of each of the trenches in the FET region.

The following detailed description and accompanying drawings provide a more complete understanding of the nature and advantages of the present subject matter.

### BRIEF DESCRIPTION OF THE DRAWINGS

In the drawings, the thicknesses of layers and regions may be exaggerated for clarity. Further, it should be appreciated that the structure shown is exemplary and may represent only a portion of a semiconductor device.

FIG. 1 is a simplified cross-section view of an exemplary integrated superjunction trench gate metal oxide semiconductor field effect transistor (MOSFET) and Schottky-based diode in accordance with an embodiment of the invention;

FIGS. 2A-2B are simplified circuit diagrams showing how conventional fast response diodes can be eliminated using an integrated MOSFET with Schottky-based diodes in accordance with an embodiment of the invention;

FIGS. 3A-3D are simplified cross-section views at various steps of a process for forming an exemplary integrated MOSFET and Schottky-based diode in accordance with an embodiment of the invention;

FIGS. 4A-4D are simplified cross-section views at various steps of a process for forming an exemplary integrated MOSFET and Schottky-based diode in accordance with another embodiment of the invention; and

FIG. 5 is a simplified cross-section view of an exemplary integrated superjunction planar gate MOSFET and Schottky-based diode in accordance with an embodiment of the invention.

### DETAILED DESCRIPTION

Embodiments of the present invention provide monolithically integrated superjunction MOSFETs with Schottky-based diodes. The resulting high voltage MOSFET devices have improved performance, lower device costs, and simpler methods of manufacture and use compared to conventional devices. Superjunction structures comprising adjacent pillars of opposite conductivity types can be used in MOSFET regions to increase breakdown voltage and reduce on resistance. The superjunction structures can be used in Schottky regions to reduce reverse leakage and forward voltage drop. The superjunction structures in the Schottky regions can also be used to reduce power loss and stress during fast switching modes. The integrated devices can improve reverse recovery without requiring carrier lifetime controls.

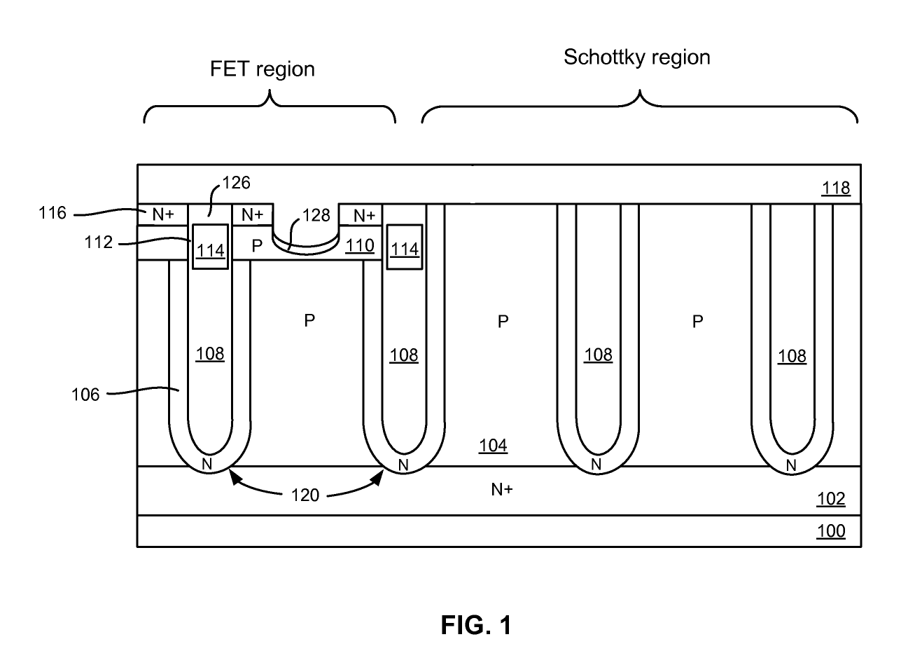

FIG. 1 is a simplified cross-section view of an exemplary integrated superjunction trench gate MOSFET and Schottky-based diode in accordance with an embodiment of the invention. It should be appreciated that embodiments of the invention may include Schottky-based diodes integrated with semiconductor devices other than MOSFETs, such as bipolar junction transistors (BJTs), insulated gate bipolar transistors (IGBTs), junction gate field effect transistors (JFETs), static induction transistors (SITs), bipolar static induction transistors, thyristors, and the like.

The device shown in FIG. 1 includes a P region 104 extending over an N+ region 102. The P region 104 may comprise an epitaxial layer and the N+ region 102 may comprise a heavily doped substrate. The N+ region 102 contacts a drain electrode 100.

The device shown in FIG. 1 also includes a plurality of trenches 120 extending into the P region 104. Although FIG. 1 shows the trenches 120 extending through the P region 104 and into the N+ region 102, in some embodiments the trenches may terminate within the P region 104. Some of the trenches 120 are disposed in a FET region of the device, and some of the trenches 120 are disposed in a Schottky region of the device. The FET region includes MOSFET devices, and the Schottky region includes Schottky-based diodes.

Each of the trenches 120 include a dielectric material 108 and a conductive layer 106 extending along at least a portion of the sidewalls and bottom. The conductive layer 106 may be n-type and form a PN junction with the surrounding P region 104. The P region 104 and the conductive layer 106 provide a superjunction structure in the FET region and Schottky-based diodes in the Schottky region. A width and dopant concentration of the conductive layer 106 may be determined to provide charge balance between the conductive layers 106 and the P region 104 between adjacent trenches 120. Also, while the trenches 120 may terminate in the P region 104 or the N+ region 102, it should be understood that up-diffusion from the N+ region 102 and out-diffusion from the conductive layers 106 during subsequent thermal cycles may extend the area of these regions.

In the FET region, each trench 120 also includes a gate electrode 114 in an upper portion of the trench 120. A body region 110 and N+ source regions 116 abut upper sidewalls of each trench 120. The conductive layer 106 extends along sidewalls of the trench 120 below the body region 110. The gate electrode 114 is insulated from the surrounding regions by a gate dielectric 112 lining upper sidewalls of the trench 120, the dielectric material 108 filling a lower portion of the trench 120, and a dielectric layer 126 filling a top portion of the trench 120 over the gate electrode 114. The dielectric layer 126 insulates the gate electrode 114 from a source contact 118 that may comprise metal. Thus, when the gate electrodes 114 are biased to an “ON” state, channels formed in the body region 110 allow current to pass through the N+ source regions 116 and the conductive layers 106. The FET region may also include a recessed region between adjacent trenches 120. The recessed region may include a P+ heavy body region 128 extending into the body region 110. The source contact 118 contacts at least the N+ source regions 116 and the P+ heavy body region 128 between the trenches 120.

In the Schottky region, the dielectric material 108 substantially fills each trench 120, and the conductive layer 106 extends substantially along the entire sidewalls and bottom of each trench 120. The source contact 118 contacts mesa surfaces between adjacent trenches 120 to form Schottky contacts. The source contact 118 also contacts the conductive layer 106 proximate an upper portion of each trench 120. The source contact 118 may form Schottky contacts with the conductive layer 106. Although not shown, the dielectric material may be recessed in each of the trenches 120 to increase a contact area between the source contact 118 and the conductive layer 106. At a lower forward bias, the Schottky-based diodes in the Schottky region will perform as conventional Schottky diodes (e.g., low forward voltage drop and low reverse recovery time). At a higher forward bias, the Schottky-based diodes in the Schottky region will perform as PN diodes with fast reverse recovery and low on resistance.

It should be appreciated that the number of trenches 120 formed in the FET region and the number of trenches 120 formed in the Schottky region may vary depending on the particular application. Further, within a die there may be more than one FET region and more than one Schottky region.

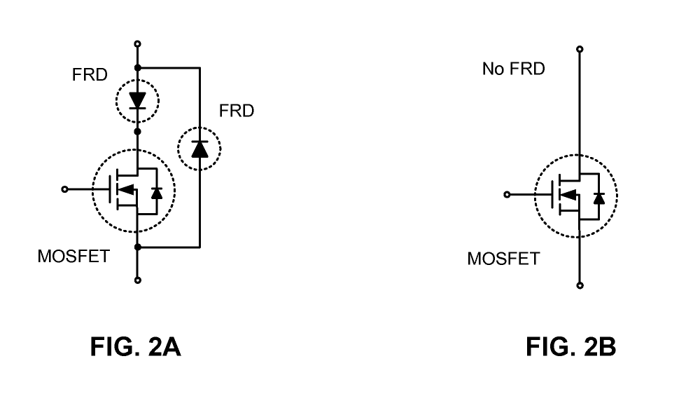

The integrated structure shown in FIG. 1 can provide improved reverse recovery compared to conventional devices. A benefit of this is shown in FIGS. 2A-2B, which are simplified circuit diagrams showing how conventional fast response diodes can be eliminated using an integrated MOSFET with Schottky-based diodes in accordance with an embodiment of the invention. When used in a half or full bridge inverter circuit, a conventional MOSFET typically requires two external fast recovery diodes (FRDs) to prevent shoot-through as illustrated in FIG. 2A. Alternatively, a method may be used to control carrier lifetime to provide increased reverse recovery. In comparison, an integrated MOSFET with Schottky-based diodes as illustrated in FIG. 2B can provide similar reverse recovery performance without requiring external FRDs or methods to control carrier lifetime.

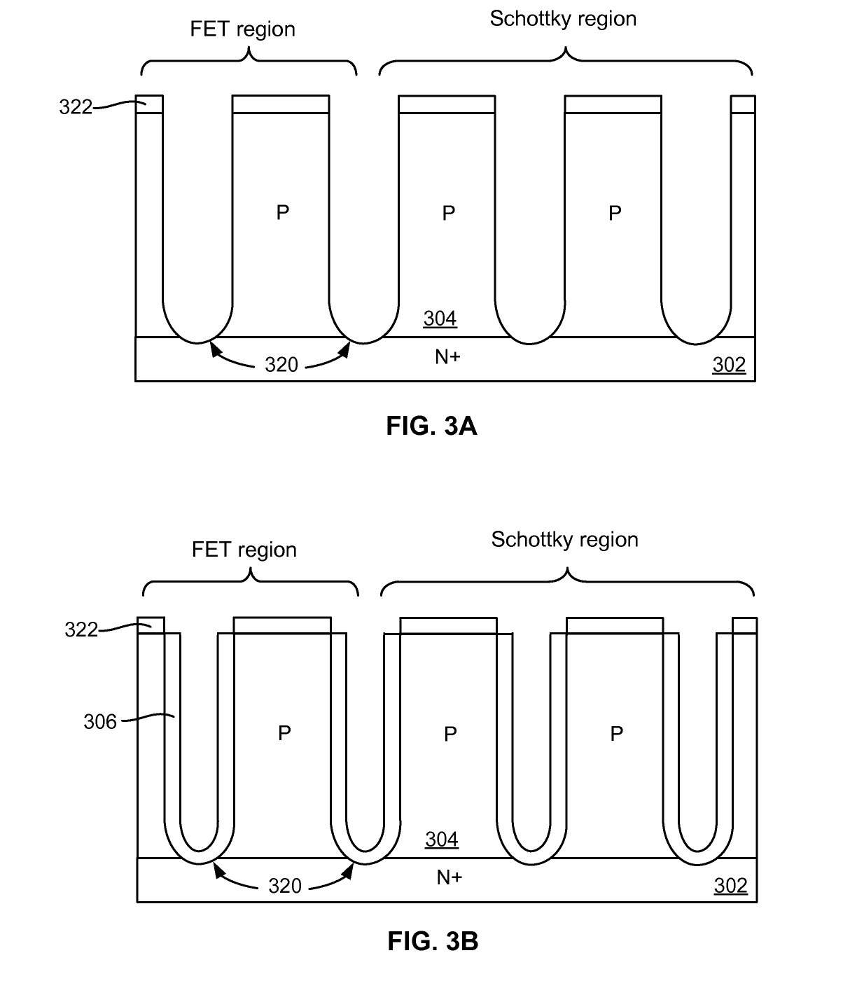

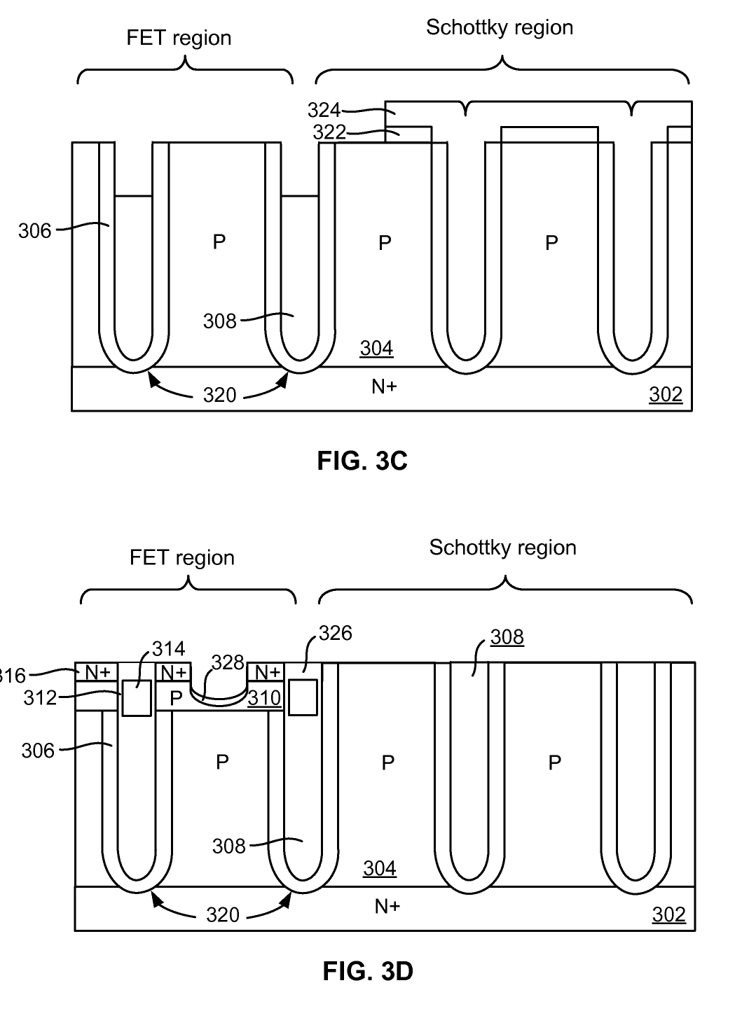

FIGS. 3A-3D are simplified cross-section views at various steps of a process for forming an exemplary integrated MOSFET and Schottky-based diode in accordance with an embodiment of the invention. In FIG. 3A, trenches 320 are formed extending into a P region 304 using hardmask layer 322 and conventional photolithography and etching techniques. The hardmask layer 322 may be comprise a dielectric such as oxide or nitride and may be formed using conventional dielectric deposition techniques.

In one embodiment, the P region 304 is an epitaxial layer formed over an N+ region 302. In some embodiments the trenches 320 may terminate in the P region 304 rather than extend into the N+ region 302. Also, a distance between adjacent trenches 320 in the FET region may be different than a distance between adjacent trenches 320 in the Schottky region.

In FIG. 3B, a conductive layer 306 is formed along sidewalls and bottom of each trench 320. The conductive layer 306 may be n-type and form a PN junction with the surrounding P region 104. The conductive layer 306 may be formed using known techniques. For example, in one embodiment the conductive layer 306 may be formed using a conventional doped epitaxial deposition technique. In this embodiment, the epitaxial growth may be selective to the P region 304 and not grow on the hardmask layer 322. In another embodiment, the conductive layer 306 may be formed using conventional dopant implant and dopant diffusion techniques. In this embodiment, the hardmask layer 322 can be used to block the implant along mesa surfaces of P region 304 between adjacent trenches.

In FIG. 3C, a dielectric 324 is formed over the entire structure using known dielectric deposition techniques. The deposition process may include a reflow to improve trench fill. In the FET region, a portion of the dielectric 324 and the hardmask layer 322 extending over mesa surfaces between adjacent trenches 320 may be removed using known photolithography and etching techniques. The dielectric 324 may be recessed in each of the trenches 320 leaving dielectric material 308 in a bottom portion of each trench 320. In the Schottky region, the dielectric 324 and the hardmask layer 322 may remain and extend over the mesa surfaces between adjacent trenches 320.

In an alternative embodiment, portions of the dielectric 324 and the hardmask layer 322 extending over mesa surfaces between adjacent trenches 320 may be removed in both the FET and Schottky regions using known etching or chemical mechanical polishing (CMP) techniques. The remaining dielectric material 308 in each trench 320 in the FET region may then be recessed using known photolithography and etching techniques.

In the FET region in FIG. 3D, a gate dielectric 312 is formed along upper sidewalls of each trench 320 and a gate electrode 314 is formed in each trench 320. The gate dielectric 312 and the gate electrode 314 may be formed using known techniques. For example, in an embodiment the gate dielectric 312 is formed along upper sidewalls of each trench 320 using conventional dielectric growth or dielectric deposition techniques. A layer of polysilicon may be deposited in each trench 320 over the dielectric material 308 and between layers of the gate dielectric 312 using conventional polysilicon deposition techniques. A portion of the polysilicon may be removed using conventional polysilicon etching techniques to leave a gate electrode 314 in each trench. The gate electrodes 314 may be doped in accordance with known techniques. A dielectric layer 326 is formed in each trench 320 over the gate electrode 314 using known dielectric deposition and etching techniques. The dielectric layer 326 may comprise a doped dielectric such as borophosphosilicate glass (BPSG), phosphosilicate glass (PSG), or the like. Body region 310 and N+ source regions 316 may be formed using conventional dopant implant and dopant diffusion techniques. A recessed region may be formed between adjacent trenches 320 extending into the body region 310 using conventional photolithography and etching techniques. A P+ heavy body region 328 may be formed along a bottom of the recessed region using known dopant implant and dopant diffusion known techniques.

In the Schottky region in FIG. 3D, the dielectric 324 and the hardmask layer 322 extending over the mesa surfaces between adjacent trenches 320 may be removed (if not previously removed) using known photolithography and etching techniques.

Although not shown in FIG. 3D, a source contact may be formed extending over the mesa regions between adjacent trenches 320 in both the FET region and the Schottky region (similar to the source contact 118 shown in FIG. 1). The source contact may comprise metal. In the FET region, the source contact may contact at least the N+ source regions 316 and the P+ heavy body region 328 between adjacent trenches 320. In the Schottky region, the source contact may contact at least the mesa surfaces between adjacent trenches 320 and the conductive layer 306 proximate an upper portion of each trench 320. The source contact forms Schottky contacts with the mesa surfaces. The source contact may also form Schottky contacts with the conductive layer 306. Although not shown, the dielectric material 308 may be recessed in each of the trenches 320 in the Schottky region to increase a contact area between the source contact and the conductive layer 306. Also, for ease of manufacturing, an inactive or unused gate electrode 314 along with a gate dielectric layer 312 and a dielectric layer 326 may be formed in each trench 320 of the Schottky region at the same time they are formed in the FET region. A drain electrode (also not shown) may be formed along a lower surface of N+ region 302 (similar to the drain electrode 100 shown in FIG. 1).

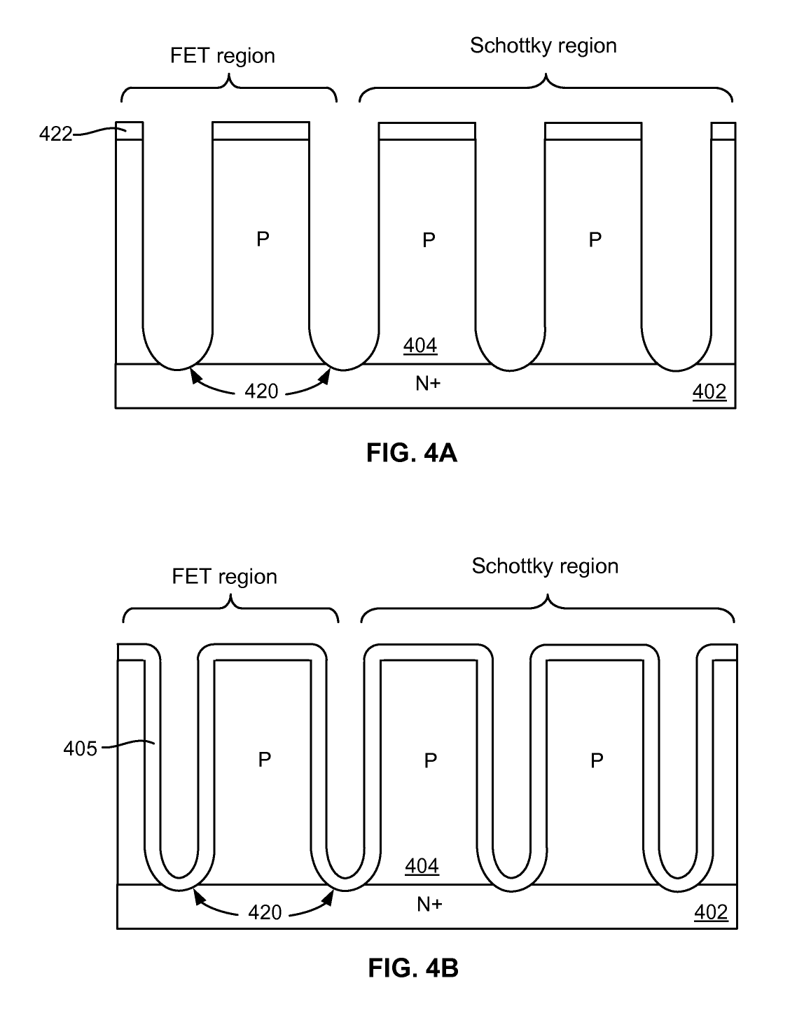

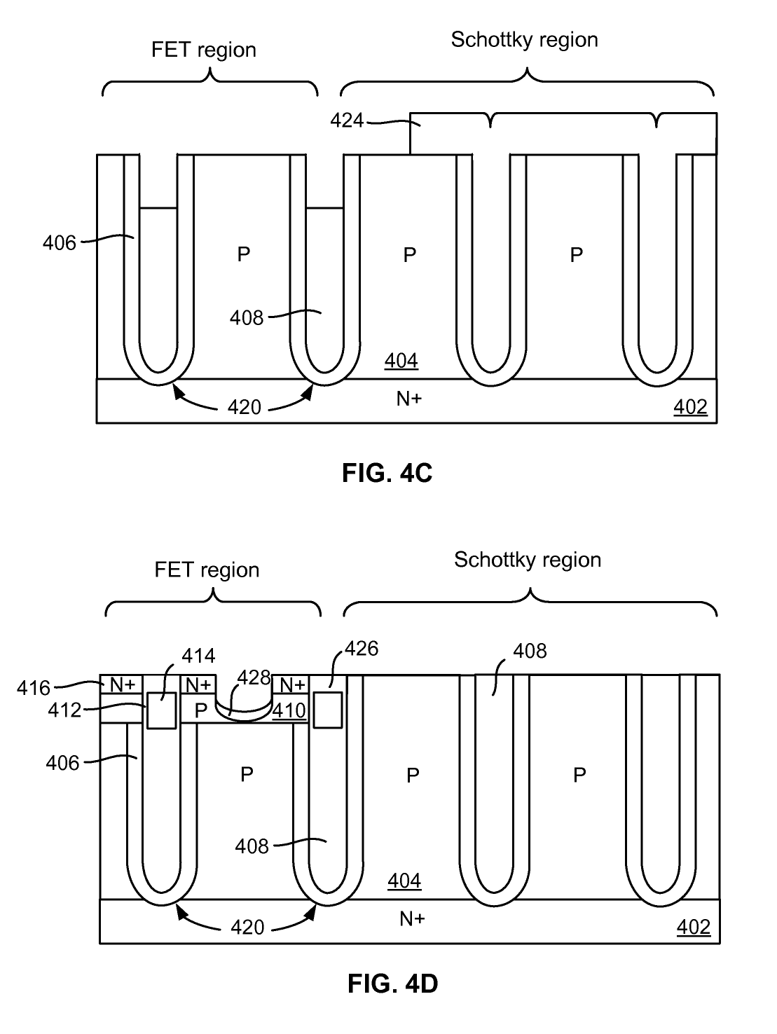

FIGS. 4A-4D are simplified cross-section views at various steps of a process for forming an exemplary integrated MOSFET and Schottky-based diode in accordance with another embodiment of the invention. FIGS. 4A-4D illustrate a method where a hardmask layer is removed before forming a conductive layer in the trenches.

In FIG. 4A, trenches 420 are formed extending into a P region 404 using a hardmask layer 422 and conventional photolithography and etching techniques. After trench formation, the hardmask layer 422 may be removed using conventional etching techniques. In FIG. 4B, a conductive film 405 is formed over mesa surfaces and along sidewalls and bottom of each trench 420. The conductive film 405 may be n-type and form a PN junction with the surrounding P region 104. The conductive film 405 may be formed using known techniques. For example, in one embodiment the conductive film 405 may be formed using a conventional doped epitaxial or doped polysilicon deposition technique. In another embodiment, the conductive film 405 may be formed using conventional dopant implant and dopant diffusion techniques.

In FIG. 4C, portions of the conductive film 405 extending over mesa surfaces are removed using known etching techniques (e.g., etch or CMP) to leave conductive layers 406 in each trench 420. A dielectric 424 is formed over the entire structure using known dielectric deposition techniques. The deposition process may include a reflow to improve trench fill. In the FET region, a portion of the dielectric 424 extending over the mesa surfaces may be removed using known photolithography and etching techniques. The dielectric 424 may be recessed in each of the trenches 420 leaving dielectric material 408 in a bottom portion of each trench 420. In the Schottky region, the dielectric 424 may remain and extend over the mesa surfaces between adjacent trenches 420. Alternatively, portions of the dielectric 424 extending over mesa surfaces between adjacent trenches 420 may be removed in both the FET and Schottky regions using known etching and/or CMP techniques. The remaining dielectric material 408 in each trench 420 in the FET region may then be recessed using known etching techniques.

In an alternative embodiment, the conductive film 405 and the dielectric 424 may be formed over the entire structure using known deposition techniques. Portions of the conductive film 405 and the dielectric 424 extending over mesa surfaces can be removed using known etching and/or CMP techniques leaving conductive layer 406 and dielectric material 408 in each trench. In the FET region, the dielectric material 408 can be further recessed using conventional photolithography and etching processes.

In the FET region in FIG. 4D, a gate dielectric 412 is formed along upper sidewalls of each trench 420 and a gate electrode 414 is formed in each trench 420. A dielectric layer 426 is formed in each trench over the gate electrode 414 using known dielectric deposition and etching techniques. Body region 410 and N+ source regions 416 may be formed using conventional dopant implant and dopant diffusion techniques. A recessed region may be formed between adjacent trenches 420 extending into the body region 410. A P+ heavy body region 428 may be formed along a bottom of the recessed region.

In the Schottky region in FIG. 4D, the dielectric 424 extending over the mesa surfaces may be removed (if not previously removed) using known photolithography and etching techniques. A source contact and drain electrode may be formed in a manner similar to that described previously with regard to FIG. 3D.

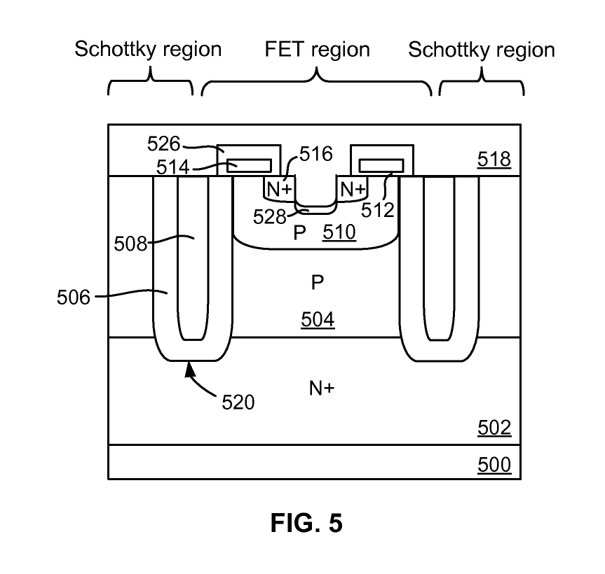

FIG. 5 is a simplified cross-section view of an exemplary integrated superjunction planar gate MOSFET and Schottky-based diode in accordance with an embodiment of the invention. The device shown in FIG. 5 includes a P region 504 extending over an N+ region 502. The P region 504 may comprise an epitaxial layer and the N+ region 502 may comprise a heavily doped substrate. The N+ region 502 contacts a drain electrode 500.

The device shown in FIG. 5 also includes a plurality of trenches 520 formed in Schottky regions. In this embodiment, the trenches 520 extend into the P region 504. In other embodiments, the trenches 520 may terminate within the P region 504. Each of the trenches 520 include a dielectric material 508 and a conductive layer 506 extending along sidewalls of the trenches 520. The conductive layer 506 may be n-type and form a PN junction with the surrounding P region 504. The conductive layer 506 provides a drift region in the FET region. The P region 504 and the conductive layer 506 provide Schottky-based diodes in the Schottky region.

In the FET region, a gate electrode 514 extends over a surface of the P region 504. A body region 510 is disposed in an upper portion of the P region 504, and N+ source regions 516 are disposed in an upper portion of the body region 510. The gate electrode 514 is insulated from the underlying regions by a gate dielectric 512. A dielectric layer 526 surrounds each gate electrode 514 along upper and side surfaces. The dielectric layer 526 insulates the gate electrodes 514 from a source contact 518. The source contact 518 may comprise metal. The FET region may also include a P+ heavy body region 528 extending into the body region 510 between adjacent gate electrodes 514. The source contact 518 contacts at least the N+ source regions 516 and the P+ heavy body region 528.

In the Schottky region, the dielectric material 508 substantially fills each trench 520, and the conductive layer 506 extends substantially along the entire sidewalls and bottom of each trench 520. The source contact 518 contacts mesa surfaces to form Schottky contacts. The source contact 518 also contacts the conductive layer 506 proximate an upper portion of each trench 520. The source contact 518 may also form Schottky contacts with the conductive layer 506. Although not shown, the dielectric material may be recessed in each of the trenches 520 to increase a contact area between the source contact 518 and the conductive layer 506. Similar to trench gate embodiments, at a lower forward bias the Schottky-based diodes in the Schottky region perform as conventional Schottky diodes (e.g., low forward voltage drop and low reverse recovery time). At higher a forward bias, the Schottky-based diodes in the Schottky region perform as PN diodes with fast reverse recovery and low on resistance. Methods of forming the planar gate structure shown in FIG. 5 would be obvious to one of ordinary skill in the art based on FIGS. 3A-3D and 4A-4D along with the accompanying text above.

Note that while the embodiments depicted in FIGS. 1, 3A-3D, 4A-4D, and 5 show re-channel FETs, p-channel FETs may be obtained by reversing the polarity of the source regions, well regions, drift region, and substrate. Further, in embodiments where the semiconductor regions include an epitaxial layer extending over a substrate, MOSFETs are obtained where the substrate and epitaxial layer are of the same conductivity type, and IGBTs are obtained where the substrate has the opposite conductivity type to that of the epitaxial layer. Further, in light of the present disclosure, it would be obvious to one or ordinary skill in the art to form other device types in accordance with embodiments of the invention

It should be understood that the above description is exemplary only, and the scope of the invention is not limited to these specific examples. The dimensions in the figures of this application are not to scale, and at times the relative dimensions are exaggerated or reduced in size to more clearly show various structural features. Additionally, while only one transistor is shown in each figure, it is to be understood that the structure illustrated may be replicated many times in an actual device.

Furthermore, it should be understood that the doping concentrations of the various elements could be altered without departing from the invention. Also, while the various embodiments described above are implemented in conventional silicon, these embodiments and their obvious variants can also be implemented in silicon carbide, gallium arsenide, gallium nitride, diamond, or other semiconductor materials. Additionally, the features of one or more embodiments of the invention may be combined with one or more features of other embodiments of the invention without departing from the scope of the invention.

Therefore, the scope of the present invention should be determined not with reference to the above description, but should instead be determined with reference to the appended claims, along with their full scope of equivalents.

What is claimed is:

1. A semiconductor structure, comprising:
a semiconductor layer of a first conductivity type;
trenches extending into the semiconductor layer; and
a conductive layer of a second conductivity type lining sidewalls and bottom of each trench and forming PN junctions with the semiconductor layer, wherein a first plurality of the trenches are disposed in a field effect transistor (FET) region of the semiconductor structure, the FET region comprising:
a body region of the first conductivity type in the semiconductor layer;
source regions of the second conductivity type in the body region; and
gate electrodes isolated from the body region and the source regions by a gate dielectric;
wherein a second plurality of the trenches are disposed in a Schottky region of the semiconductor structure, the Schottky region comprising:
a conductive material contacting mesa surfaces of the semiconductor layer between adjacent ones of the second plurality of the trenches to form Schottky contacts, the conductive material also contacting the conductive layer proximate an upper portion of the second plurality of the trenches.

2. The semiconductor structure of claim 1 further comprising a dielectric material substantially filling a center portion of each trench between the conductive layer lining the sidewalls and the bottom of each trench.

3. The semiconductor structure of claim 1 wherein the first conductivity type is p-type and the second conductivity type is n-type.

4. The semiconductor structure of claim 1 wherein the first conductivity type is n-type and the second conductivity type is p-type.

5. The semiconductor structure of claim 1 wherein the semiconductor layer extends over a substrate of the second conductivity type, and the trenches extend through the semiconductor layer.

6. The semiconductor structure of claim 5 wherein the semiconductor layer comprises an epitaxial layer.

7. The semiconductor structure of claim 1 wherein one of the gate electrodes are disposed in each of the first plurality of the trenches, and the body region and the source regions abut the sidewalls of the first plurality of the trenches.

8. The semiconductor structure of claim 1 wherein the conductive material forms Schottky contacts with the conductive layer in the Schottky region.

9. The semiconductor structure of claim 1 wherein the conductive material comprises metal.

10. A semiconductor structure, comprising:
a field effect transistor (FET) region comprising:
a body region of a first conductivity type in a semiconductor region;
source regions of a second conductivity type in the body region;
gate electrodes isolated from the body region and the source regions by a gate dielectric; and
a conductive material extending over the FET region and contacting the source regions;
a Schottky region comprising:
a first plurality of trenches extending into the semiconductor region; and
a conductive layer of the second conductivity type lining sidewalls and bottom of each of the first plurality of trenches and forming PN junctions with the semiconductor region, wherein the conductive material extends over the Schottky region and contacts mesa surfaces of the semiconductor region between adjacent ones of the first plurality of trenches and contacts the conductive layer proximate an upper portion of the first plurality of trenches.

11. The semiconductor structure of claim 10 wherein the conductive material forms Schottky contacts with the mesa surfaces of the semiconductor region and with the conductive layer proximate the upper portion of the first plurality of trenches.

12. The semiconductor structure of claim 10 wherein the conductive material comprises metal.

13. The semiconductor structure of claim 10 wherein the semiconductor region comprises an epitaxial layer of the first conductivity type extending over a substrate of the second conductivity type, and the first plurality of trenches extend through the epitaxial layer.

14. The semiconductor structure of claim 10 wherein the gate electrodes are disposed over an upper surface of the semiconductor region, the gate dielectric extending between each gate electrode and the semiconductor region, and each gate electrode overlaps the body region and at least one of the source regions along the upper surface of the semiconductor region.

15. The semiconductor structure of claim 10 wherein the FET region further comprises a second plurality of trenches extending into the semiconductor region, the conductive layer lining sidewalls and bottom of each of the second plurality of trenches and forming PN junctions with the semiconductor region, and wherein one of the gate electrodes are disposed in each of the second plurality of trenches, and the body region and the source regions abut the sidewalls of the second plurality of trenches.

16. The semiconductor structure of claim 10 further comprising a dielectric material substantially filling a center portion of each of the first plurality of trenches between the conductive layer lining the sidewalls and the bottom of each of the first plurality of trenches.

17. The semiconductor structure of claim 10 wherein the first conductivity type is p-type and the second conductivity type is n-type.

18. The semiconductor structure of claim 10 wherein the first conductivity type is n-type and the second conductivity type is p-type.

19. A method of forming a semiconductor structure having a field effect transistor (FET) region and a Schottky region, the method comprising:
forming trenches extending into a semiconductor region;
forming a conductive layer lining sidewalls and bottom of each trench, the conductive layer forming PN junctions with the semiconductor region;
in the FET region, forming a body region of a first conductivity type in the semiconductor region, source regions of a second conductivity type in the body region, and forming gate electrodes isolated from the body region and the source regions by a gate dielectric; and
in the Schottky region, forming a conductive material contacting mesa surfaces of the semiconductor region between adjacent ones of the trenches to form Schottky contacts and contacting the conductive layer proximate an upper portion of the trenches.

20. The method of claim 19 wherein the conductive material forms Schottky contacts with the conductive layer in the Schottky region.

21. The method of claim 19 wherein the conductive material comprises metal.

22. The method of claim 19 wherein forming the conductive layer comprises growing an epitaxial layer along the sidewalls and the bottom of each trench.

23. The method of claim 19 wherein forming the conductive layer comprises implanting a dopant into the sidewalls and the bottom of each trench.

24. The method of claim 19 wherein the semiconductor region comprises an epitaxial layer of the first conductivity type extending over a substrate of the second conductivity type, the trenches extending through the epitaxial layer.

25. The method of claim 19 wherein the trenches are formed only in the Schottky region, and in the FET region the gate electrodes are formed over an upper surface of the semiconductor region such that the gate dielectric extends between each gate electrode and the semiconductor region and each gate electrode overlaps the body region and at least one of the source regions along the upper surface of the semiconductor region.

26. The method of claim 19 wherein one of the gate electrodes are formed in each of the trenches in the FET region, and the body region and the source regions abut the sidewalls of each of the trenches in the FET region.

27. The method of claim 19 wherein the first conductivity type is p-type and the second conductivity type is n-type.

28. The method of claim 19 wherein the first conductivity type is n-type and the second conductivity type is p-type.
